(19) United States
(12) Patent Application Publication
(10) Pub. No.: US 2026/0305346 A1
(43) Pub. Date: Oct. 1, 2026

(54) SEMICONDUCTOR PACKAGE

(71) Applicant: DeepWave, Inc., Santa Clara, CA (US)

(72) Inventors: Dae-kyu CHOI, Suwon-si (KR); Kuk Hwan LEE, Suwon-si (KR)

(73) Assignee: DeepWave, Inc., Santa Clara, CA (US)

(21) Appl. No.: 19/093,988

(22) Filed: Mar. 28, 2025

(51) Int. Cl. H10W 40/47; H10W 40/22; H10W 70/60; H10W 70/698; H10W 90/00; H10B 80/00

(52) U.S. Cl. CPC H10W 40/47; H10W 40/22; H10W 70/611; H10W 70/698; H10W 90/00; H10W 90/401; H10B 80/00

(57) ABSTRACT

Provided are a semiconductor package and a method of fabricating the same. The semiconductor package includes a package substrate including a first base substrate and a first wiring layer, an interposer including a second base substrate and a second wiring layer, and located on the package substrate, a first chip located on the interposer, and a second chip located on the interposer, wherein one or more of the first base substrate and the second base substrate are silicon (Si) substrates which are substantially undoped or regionally non-uniformly doped.

### BACKGROUND OF THE INVENTION

### 1. Field of the Invention

The present disclosure relates to a semiconductor package.

### 2. Description of the Related Art

The demand for high performance and low power consumption of electronic devices is increasing. In particular, in fields such as artificial intelligence, high performance computing, graphic processing, and the like, a large amount of data needs to be processed in real time.

Semiconductor technology has been continuously developing to meet this demand. For example, a high bandwidth memory (HBM) refers to a memory architecture in which DRAM dies are vertically stacked. The HBM that provides a large bandwidth may be integrated into one package with a computing device such as a graphic processing unit (GPU) to shorten a data transmission distance, thereby suppressing a bottleneck phenomenon and maximizing the performance of the computing device.

However, a memory that supports a high bandwidth, such as HBM, consumes more power as data transmission speed increases, which may cause heat generation problems. If a heat generation phenomenon in a semiconductor package is not relieved, it may lead to performance degradation and reliability problems of the computing device.

### SUMMARY OF THE INVENTION

Aspects of the present disclosure provide a semiconductor package with a reduced fabrication cost, high reliability, and improved heat dissipation characteristics.

It will be understood that technical problems of the present disclosure are not limited to the aforementioned problems and other technical problems not referred to herein will be clearly understood by those skilled in the art from disclosures below.

According to an embodiment of the present disclosure, there is provided a semiconductor package comprising: a package substrate comprising a first base substrate and a first wiring layer; an interposer comprising a second base substrate and a second wiring layer, and located on the package substrate; a first chip located on the interposer; and a second chip located on the interposer, wherein one or more of the first base substrate and the second base substrate are silicon (Si) substrates which are substantially undoped or regionally non-uniformly doped.

The first chip may be a memory element, and the second chip may be a processing element.

The first base substrate may be an undoped silicon substrate, and a silicon purity of the silicon substrate may be 99.99 % or more and 99.99999999 % or less.

The silicon substrate may not substantially contain phosphorus (P) and boron (B), and the silicon substrate may have a polycrystalline structure or an amorphous structure.

The first base substrate may comprise a non-uniformly doped silicon substrate, which is partially doped with boron (B) or phosphorus (P), a resistivity of the silicon substrate may range from several hundred Ω·cm to several thousand Ω·cm, and the silicon substrate may have a band gap of 9.1 eV or more, or a breakdown voltage of 10 MV/cm or more.

The semiconductor package may further comprise a cooling member located on a bottom surface of the package substrate, wherein a coolant fluid flowing along an internal space of the cooling member is in contact with an insulating layer of the package substrate.

The semiconductor package may further comprise a support member located on the package substrate and at least partially surrounding the interposer.

A first region and a second region may be defined on the package substrate, and in plan view, the support member may be located in the second region and may not be located in the first region.

The first base substrate may be made of silicon (Si), the first wiring layer may comprise a metal layer, and the metal layer may not exist in the second region.

The package substrate may further comprise an insulating layer directly located on the first base substrate, and in the second region, the insulating layer may be at least partially exposed, and the insulating layer may be in contact with the support member.

In the second region, the first base substrate may be at least partially exposed, and the first base substrate may be in contact with the support member.

The first base substrate may have a plurality of holes, and the plurality of holes may comprise at least one second hole located in the second region.

The second hole may overlap the support member in a lamination direction.

The first base substrate may have at least one groove located in the second region, and the groove may overlap the support member in a lamination direction.

The first base substrate may have at least one hole and/or groove located in the second region, and the semiconductor package may further comprise a thermal interface interlayer overlapping the at least one hole and/or groove and in contact with the support member and the package substrate.

The support member may have a first fluid space.

The first base substrate may have at least one hole located in the second region, and the hole may be connected to the first fluid space.

The semiconductor package may further comprise a heat dissipation member located on the support member and spaced apart from the package substrate with the interposer located between the heat dissipation member and the package substrate, wherein the heat dissipation member has a second fluid space, and the second fluid space is connected to the first fluid space.

The second fluid space may at least partially overlap the first chip or the second chip in the lamination direction.

The first fluid space may be filled with liquid.

Specific details of other embodiments are included in the detailed description.

According to embodiments of the present disclosure, at least one base substrate between a package substrate and an interposer is made of silicon (Si), so that the fabrication cost may be reduced, and the reliability and heat dissipation characteristics may be improved.

The effects according to the embodiments of the present disclosure are not limited to the contents exemplified above.

### BRIEF DESCRIPTION OF THE DRAWINGS

The above and other objects, features, and advantages of the present disclosure will be more clearly understood from the following detailed description taken in conjunction with the accompanying drawings, in which:

FIG. 1 is a cross-sectional view of a semiconductor package according to an embodiment of the present disclosure.

FIG. 2 is a cross-sectional view of the package substrate of FIG. 1.

FIG. 3 is a cross-sectional view of the interposer of FIG. 1.

FIG. 4 is a cross-sectional view of a package substrate of a semiconductor package according to another embodiment of the present disclosure.

FIG. 5 is a schematic diagram of a semiconductor package according to still another embodiment of the present disclosure.

FIG. 6 is a cross-sectional view of the semiconductor package of FIG. 5.

FIG. 7 is an enlarged view showing area A of FIG. 6.

FIG. 8 is a cross-sectional view of a semiconductor package according to still another embodiment of the present disclosure.

FIG. 9 is a cross-sectional view of the package substrate of FIG. 8.

FIG. 10 is a cross-sectional view of a semiconductor package according to still another embodiment of the present disclosure.

FIG. 11 is a cross-sectional view of a semiconductor package according to still another embodiment of the present disclosure.

FIG. 12 is a cross-sectional view of the package substrate of FIG. 11.

FIG. 13 is a cross-sectional view of a semiconductor package according to still another embodiment of the present disclosure.

FIG. 14 is a cross-sectional view of a semiconductor package according to still another embodiment of the present disclosure.

FIG. 15 is a cross-sectional view of the interposer of FIG. 14.

FIGS. 16 to 26 are cross-sectional views of a semiconductor package according to still other embodiments of the present disclosure.

FIG. 27 is a schematic diagram of a semiconductor package according to still another embodiment of the present disclosure.

FIG. 28 is a cross-sectional view of the semiconductor package of FIG. 27.

FIG. 29 is an enlarged view showing the vicinity of a cooling member and a package substrate of FIG. 28.

### DETAILED DESCRIPTION OF THE INVENTION

Advantages and features of the present disclosure and methods of accomplishing the same may be understood more readily by reference to the following detailed description of preferred embodiments and the accompanying drawings. The present disclosure may, however, be embodied in many different forms and should not be construed as being limited to the embodiments set forth herein. Rather, these embodiments are provided to convey the concept of the disclosure to those skilled in the art.

Various changes may be made to embodiments presented in the present disclosure. Examples described below are not intended to limit embodiments of the present disclosure, and should be understood to include all modifications, equivalents, or alternatives thereto.

As used herein, the term “and/or” includes any and all combinations of one or more of the associated listed items. As used herein, the singular forms “a”, “an” and “the” are intended to include the plural forms as well, unless clearly stated otherwise. It will be further understood that the terms “comprises” and/or “comprising,” when used in this specification, specify the presence of stated components, but do not preclude the presence or addition of one or more other components. A numerical range expressed using “to” indicates a numerical range including values stated before and after “to” as the lower and upper limits. A numerical range expressed using “about” or “approximately” indicates a value or a numerical range within 20 % of the value or the numerical range stated after “about” or “approximately”.

In this specification, ordinal modifiers such as “first component”, “second component”, “first-first component”, etc., when referring to components, are only used to distinguish one component from another. Therefore, the first component referred to below may be referred to as the second component within the scope of the present disclosure. For example, what is referred to as the first component in one embodiment may be referred to as the second component in another embodiment.

In the drawings, the present disclosure is not limited to the illustrated form and components may be enlarged or reduced in size, thickness, width, length, and the like.

Spatially relative terms, such as “above,” “upper,” “on,” “below,” “beneath,” “lower,” and the like, may be used herein for ease of description to describe one element or feature’s relationship to another element(s) or feature(s) as illustrated in the figures. It will be understood that the spatially relative terms may encompass a different orientation of the device other than the orientation depicted in the figures. For example, if the device in the figures is turned over, elements described as “below” or “beneath” other elements or features would then be oriented “above” the other elements or features.

The first direction X means any direction on the plane, and the second direction Y means another direction intersecting or orthogonal to the first direction X within the plane. The third direction Z means another direction intersecting or perpendicular to the plane. The term “overlap” or “overlapping” may be understood to mean one or more components or features are aligned or positioned along at least one common direction. For example, if a first component and a second component are positioned along a same X-direction, where the first component is positioned before or after the second component along the X-direction, the first component and the second component may be considered to overlap in the X-direction.

Unless otherwise defined, the “plane” refers to a plane perpendicular to the third direction Z.

Hereinafter, the present disclosure is described in detail with reference to the accompanying drawings.

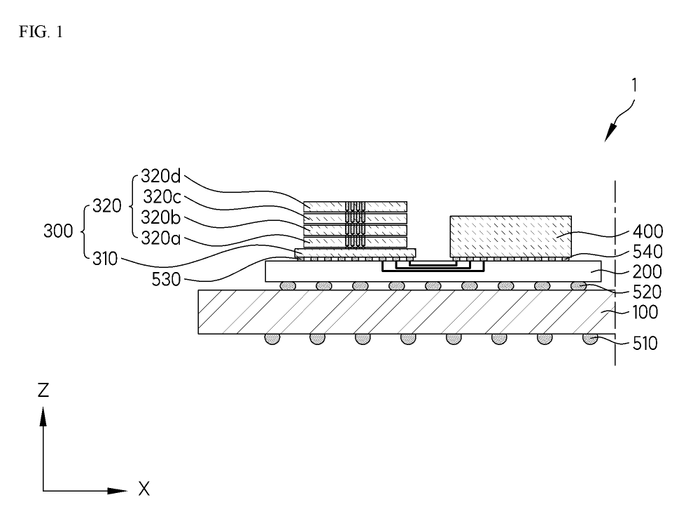

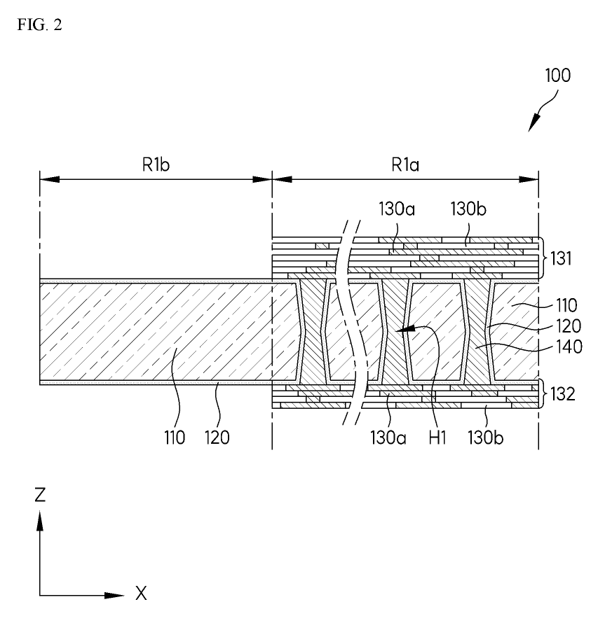

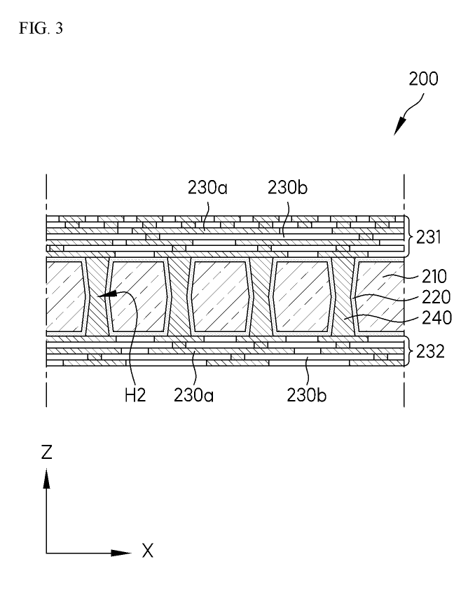

FIG. 1 is a cross-sectional view of a semiconductor package according to an embodiment of the present disclosure. FIG. 2 is a cross-sectional view of the package substrate of FIG. 1. FIG. 3 is a cross-sectional view of the interposer of FIG. 1.

Referring to FIGS. 1 to 3, a semiconductor package 1 according to this embodiment includes a package substrate 100, an interposer 200, a first chip 300, a second chip 400, and connection members 510, 520, 530, and 540.

The package substrate 100 (or first substrate) may include a first base substrate 110, a first insulating layer 120, first wiring layers 131 and 132, and a first conductive portion 140 (or first via) located in a first via hole H1.

The first base substrate 110 may have a plurality of first via holes H1 (or package via holes). The first via hole H1 may penetrate the first base substrate 110. The width of the first via hole H1 may vary depending on the position in a third direction Z. The first via hole H1 may form an inclined inner sidewall. Specifically, the inner sidewall of the first via hole H1 may include a first surface inclined toward the center side from the top surface of the first base substrate 110 and a second surface inclined toward the center side from the bottom surface of the first base substrate 110, and the first surface and the second surface may be inclined in opposite directions.

The size, e.g., the maximum diameter in plan view, of the first via hole H1 may be about 30 μm or less, about 20 μm or less, or about 10 μm or less. The lower limit of the diameter of the first via hole H1 is not particularly limited, but may be preferably 5 μm or more in terms of forming the first conductive portion 140.

The first via hole H1 may be repeatedly formed in a first direction X and a second direction intersecting the first direction X. A minimum pitch between the plurality of first via holes H1 may be about 100 μm or less, about 50 μm or less, or about 30 μm or less.

The first insulating layer 120 may be directly located on the top surface and/or bottom surface of the first base substrate 110. In some embodiments, the first insulating layer 120 may be located on the inner sidewall of the first via hole H1. The first insulating layer 120 may include a material substantially having an electrical insulation property. For example, the first insulating layer 120 may include at least one of silicon dioxide (SiO₂), silicon nitride (Si₃N₄), or silicon oxynitride (SiOxNy, where x and y are the same or different numbers). As a non-limiting example, the resistivity of the first insulating layer 120 may be equal to or greater than 5,000 Ω·cm.

The first wiring layers 131 and 132 may function as a redistribution layer of the package substrate 100. Specifically, the first upper wiring layer 131 may be at least partially located on the top surface of the first base substrate 110, and the first lower wiring layer 132 may be at least partially located on the bottom surface of the first base substrate 110. The first wiring layers 131 and 132 may be laminated in contact with the first insulating layer 120.

Each of the first upper wiring layer 131 and the first lower wiring layer 132 may include a plurality of layers. Each of the first upper wiring layer 131 and the first lower wiring layer 132 may include a first metal layer 130a and a first wiring insulating layer 130b. Further, the first conductive portion 140 may electrically connect the first metal layer 130a of the first upper wiring layer 131 to the first metal layer 130a of the first lower wiring layer 132. That is, the first wiring layers 131 and 132 may include the first metal layers 130a connected in the horizontal direction and the vertical direction and redistribute a connection pad to enable desired electrical connection together with the first conductive portion 140. Each of the first metal layer 130a and/or the first conductive portion 140 may include a highly conductive material such as copper, aluminum, silver, tin, gold, tungsten, nickel, lead, titanium, or an alloy thereof.

The first metal layers 130a of the first wiring layers 131 and 132 may be at least partially exposed to the top surface and/or the bottom surface, and the exposed first metal layer 130a may form the connection pad of the package substrate 100. The connection pads exposed to the top surface and the bottom surface of the package substrate 100 may function as input/output pads and may enable efficient electrical connection.

As a non-limiting example, the first connection member 510 having electrical conductivity may be located on the connection pad exposed to the bottom surface of the package substrate 100, e.g., a part of the first metal layer 130a of the first lower wiring layer 132. Further, the first connection member 510 may function as a path for electrical connection with another printed circuit board (not shown). The first connection member 510 may be a solder ball, but may also be a pin, a land, or the like in another embodiment.

A first region R1a and a second region R1b may be defined on the package substrate 100. The first region R1a may be defined as a region where the first wiring layers 131 and 132 are located, and the second region R1b may be defined as a region where the first wiring layers 131 and 132 are not located. More specifically, at least the first metal layers 130a of the first wiring layers 131 and 132 may not exist in the second region R1b. In plan view, the second region R1b may have a shape that at least partially surrounds the first region R1a. That is, the second region R1b may be located on the edge side compared to the first region R1a.

In an exemplary embodiment, the first via hole H1 of the first base substrate 110 may exist only in the first region R1a. In other words, the component referred to as the first via hole H1 may not exist in the second region R1b. The first base substrate 110 and the first insulating layer 120 may exist in the second region R1b, and the first insulating layer 120 may be exposed without being covered by the first wiring layers 131 and 132.

The interposer 200 may be mounted on the package substrate 100. Although FIG. 1 illustrates a case where one interposer 200 is located on one package substrate 100, a plurality of interposers may be located on one package substrate 100 in another embodiment.

The interposer 200 (or second substrate, or bridge substrate) may include a second base substrate 210, a second insulating layer 220, second wiring layers 231 and 232, and a second conductive portion 240 (or second via) located in a second via hole H2.

The thickness of the second base substrate 210 in the third direction Z may be less than the thickness of the first base substrate 110. The second base substrate 210 may have a plurality of second via holes H2 (or interposer via holes). The second via hole H2 may penetrate the second base substrate 210. The width of the second via hole H2 may vary depending on the position in the third direction Z. The second via hole H2 may have the same shape as that of the first via hole H1. Further, the size (e.g., diameter) and/or pitch of the second via hole H2 may be substantially the same as or different from those of the first via hole H1.

The second insulating layer 220 may be directly located on the top surface and/or bottom surface of the second base substrate 210. In some embodiments, the second insulating layer 220 may be located on the inner sidewall of the second via hole H2. The material and electrical characteristics of the second insulating layer 220 may be substantially the same as those of the first insulating layer 120.

The second wiring layers 231 and 232 may function as a redistribution layer of the interposer 200. Specifically, the second upper wiring layer 231 may be at least partially located on the top surface of the second base substrate 210, and the second lower wiring layer 232 may be at least partially located on the bottom surface of the second base substrate 210. The second wiring layers 231 and 232 may be laminated in contact with the second insulating layer 220.

Each of the second upper wiring layer 231 and the second lower wiring layer 232 may include a plurality of layers. Each of the second upper wiring layer 231 and the second lower wiring layer 232 may include a second metal layer 230a and a second wiring insulating layer 230b. Further, the second conductive portion 240 may electrically connect the second metal layer 230a of the second upper wiring layer 231 to the second metal layer 230a of the second lower wiring layer 232. That is, the second wiring layers 231 and 232 may include the second metal layers 230a connected in the horizontal direction and the vertical direction and redistribute the connection pad to enable desired electrical connection together with the second conductive portion 240. Each of the second metal layer 230a and/or the second conductive portion 240 may include a highly conductive material such as copper, aluminum, silver, tin, gold, tungsten, nickel, lead, titanium, or an alloy thereof.

The second metal layers 230a of the second wiring layers 231 and 232 may be at least partially exposed to the top surface and/or the bottom surface, and the exposed second metal layer 230a may form the connection pad of the interposer 200. The connection pads exposed to the top surface and the bottom surface of the interposer 200 may function as input/output pads and may enable efficient electrical connection.

As a non-limiting example, the second connection member 520 having electrical conductivity may be located on the connection pad exposed to the bottom surface of the interposer 200, e.g., a part of the second metal layer 230a of the second lower wiring layer 232. Further, the second connection member 520 may be in contact with the connection pad exposed to the top surface of the package substrate 100, e.g., the first metal layer 130a of the first upper wiring layer 131, and function as a path for electrical connection between the interposer 200 and the package substrate 100. The second connection member 520 may be a solder bump, for example, a controlled collapse chip connection bump (C4 bump). Although not shown in the drawing, the space between the package substrate 100 and the interposer 200 may be filled with an underfill.

In an exemplary embodiment, the first base substrate 110 and the second base substrate 210 may include the same material or different materials, and one or more of the first base substrate 110 and the second base substrate 210 may include silicon (Si) or consist of silicon. That is, one or more of the first base substrate 110 and the second base substrate 210 may be silicon substrates.

The silicon substrate may be a silicon substrate (e.g., a silicon wafer) that is substantially undoped (without doping), or may be a regionally non-uniformly doped silicon substrate, which is only partially doped with impurities.

First, when the first base substrate 110 and/or the second base substrate 210 are an undoped silicon substrate, the first base substrate 110 and/or the second base substrate 210 may not contain boron (B) and/or phosphorus (P) elements, or may contain only unintended trace amounts of boron and/or phosphorus.

In this case, the silicon purity of the first base substrate 110 and/or the second base substrate 210 may be about 99.99999999 % or less. The lower limit of the silicon purity may be about 99.99 % or more, about 99.999 % or more, about 99.9999 % or more, about 99.99999 % or more, about 99.999999 % or more, or about 99.9999999 % or more.

When the silicon purity is within the above range, each of the first base substrate 110 and/or the second base substrate 210 may further include one or more elements selected from oxygen (O), carbon (C), iron (Fe), aluminum (Al), copper (Cu), calcium (Ca), boron (B), phosphorus (P), nitrogen (N), and sulfur (S). In an exemplary embodiment, the impurity concentration of the group consisting of oxygen (O), carbon (C), iron (Fe), aluminum (Al), copper (Cu), calcium (Ca), boron (B), phosphorus (P), nitrogen (N), and sulfur (S) in the first base substrate 110 and/or the second base substrate 210 may be about 0.0000001 % or more and 0.01 % or less, about 0.0000001 % or more and 0.001 % or less, about 0.0000001 % or more and 0.0001 % or less, about 0.0000001 % or more and 0.00001 % or less, or about 0.0000001 % or more and 0.000001 % or less.

As a non-limiting example, the first base substrate 110 and/or the second base substrate 210 as a whole may each have the concentration of each of boron and phosphorus elements, which is about 10¹⁴atoms/cm³ or less, about 10¹³atoms/cm³ or less, about 10¹²atoms/cm³ or less, about 10¹¹atoms/cm³ or less, about 10¹⁰atoms/cm³ or less, about 10⁹atoms/cm³ or less, about 10⁸atoms/cm³or less, about 10⁷atoms/cm³ or less, about 10⁶atoms/cm³ or less, or about 10⁵atoms/cm³ or less.

Additionally, the first base substrate 110 and/or the second base substrate 210 may each have a monocrystalline, polycrystalline, or amorphous structure. Preferably, the first base substrate 110 and/or the second base substrate 210 may each have a polycrystalline structure or an amorphous structure. More preferably, the first base substrate 110 and/or the second base substrate 210 may each have a polycrystalline structure.

In another embodiment, the first base substrate 110 and/or the second base substrate 210 may be a silicon substrate that is only partially doped with impurities, i.e., a regionally non-uniformly doped silicon substrate. At this time, the purity of silicon in an undoped arbitrary unit area, for example, an area of 1.0 cm² or a volume of 1.0 cm³, may be about 99.99 % to 99.99999999 %. And the purity of silicon in a doped arbitrary unit area may be lower than that.

Specifically, the unit area of any region (undoped region) of the first base substrate 110 and/or the second base substrate 210 may be substantially undoped as described above, and the concentration of impurity elements (e.g., elements of the group consisting of oxygen (O), carbon (C), iron (Fe), aluminum (Al), copper (Cu), calcium (Ca), boron (B), phosphorus (P), nitrogen (N), and sulfur (S)) may be about 0.0000001 % or more and 0.01% or less, about 0.0000001 % or more and 0.001 % or less, about 0.0000001 % or more and 0.0001 % or less, about 0.0000001 % or more and 0.00001 % or less, or about 0.0000001 % or more and 0.000001 % or less.

Alternatively, in the unit area in the undoped region, the concentration of each of boron and phosphorus elements may be about 10¹⁴atoms/cm³ or less, about 10¹³atoms/cm³ or less, about 10¹²atoms/cm³ or less, about 10¹¹atoms/cm³ or less, about 10¹⁰atoms/cm³ or less, about 10⁹atoms/cm³ or less, about 10⁸ atoms/cm³ or less, about 10⁷ atoms/cm³ or less, about 10⁶atoms/cm³ or less, or about 10⁵ atoms/cm³ or less.

On the other hand, the unit area of another region (doped region) of the first base substrate 110 and/or the second base substrate 210 may be partially doped with an impurity element such as a boron element and/or a phosphorus element, and the concentration of the impurity element per unit area may be about 0.000001 % or more, about 0.00001 % or more, about 0.0001 % or more, about 0.001 % or more, or about 0.01 % or more.

Alternatively, in the unit area of the doped region, the concentration of at least one of boron and phosphorus elements may be about 10¹⁵atoms/cm³or more, or about 10¹⁶atoms/cm³ or more. The upper limit of the concentration of a boron element or a phosphorus element may be, for example, about 10²⁰atoms/cm³or less. An electrode is provided on the doped region, and the doped region can function as an electron channel.

In other words, the concentration of a boron or phosphorus element in the doped region may be about 1.2 times or more, about 1.4 times or more, about 1.6 times or more, about 1.8 times or more, or about 2 times or more the concentration of the element in the undoped region.

In an exemplary embodiment, the resistivity of the substantially undoped or partially doped silicon substrate, i.e., the first base substrate 110 and/or the second base substrate 210, may range from several hundred Ω·cm to several thousand Ω·cm. That is, the lower limit of resistivity may be about 100 Ω·cm, about 500 Ω·cm, or about 999 Ω·cm. Additionally, the upper limit of resistivity may be about 9,999 Ω·cm, about 5,000 Ω·cm, or about 1,000 Ω·cm.

Additionally, the band gap of the first base substrate 110 and/or the second base substrate 210 may be very large, such as 9.1 eV or more. Here, the band gap may mean the difference between the valence band and the conduction band. The breakdown voltage of the first base substrate 110 and/or the second base substrate 210 may be 10 MV/cm or more. Here, the breakdown voltage may mean the voltage at which the insulation properties are lost.

The first chip 300 and the second chip 400 may be mounted on the interposer 200. Both the first chip 300 and the second chip 400 may be electrically connected to the interposer 200 to have a 2.5D package structure. Each of the first chip 300 and the second chip 400 may be a module including a semiconductor element.

In an exemplary embodiment, the first chip 300 may include a memory element, for example, a high bandwidth memory (HBM), and the second chip 400 may include a processing element, for example, a graphic processing unit (GPU), a central processing unit (CPU), a neural processing unit (NPU), an application processor (AP), or a processor such as a system on chip (SoC), e.g., an application specific integrated circuit (ASIC).

The first chip 300 and the second chip 400 may transmit data and/or a power signal to each other through at least the second upper wiring layer 231 of the interposer 200. Although FIG. 1 illustrates a case where one first chip 300 and one second chip 400 are located on one interposer 200, in other embodiments, a plurality of first chips 300 may be provided, and one second chip 400 may transmit and receive data and/or power to and from the plurality of the first chips 300.

The first chip 300 may include a plurality of die stacks. Specifically, the first chip 300 may include a buffer die 310 (or base die, or logic die, or master die) and a plurality of memory dies 320 (or core die, or slave die) that are stacked in the third direction Z. Although FIG. 1 illustrates a case where the memory dies 320 include four dies including a first memory die 320a, a second memory die 320b, a third memory die 320c, and a fourth memory die 320d, the present disclosure is not limited thereto.

The buffer die 310 may be located at the lowermost layer of the laminated body of the first chip 300 and may manage a memory interface and perform a signal path optimization function. That is, the buffer die 310 may include a component for data input/output coordination between the memory dies 320 of the first chip 300 and/or data input/output coordination between the first chip 300 and the second chip 400. The buffer die 310 may have a physical layer function. The memory dies 320 may include a plurality of dies, and each die may include a memory cell to perform an operation of reading and writing data. Each of the memory dies 320 may be a DRAM.

As a non-limiting example, the third connection member 530 having electrical conductivity may be located on the connection pad exposed to the bottom surface of the first chip 300. Further, the third connection member 530 may be in contact with the connection pad exposed to the top surface of the interposer 200, that is, the second metal layer 230a of the second upper wiring layer 231, and may function as a path for electrical connection between the first chip 300 and the interposer 200. The third connection member 530 may be a solder bump, for example, a micro bump. Further, the buffer die 310 and the plurality of memory dies 320 that are stacked in the third direction Z may also be vertically connected to the micro bump. Although not shown in the drawing, the space between the interposer 200 and the first chip 300 may be filled with an underfill.

The second chip 400 may include at least one die. Although not shown in the drawing, the second chip 400 may also include a plurality of die stacks. The second chip 400 and the first chip 300 may be located to overlap at least partially in the horizontal direction, for example, in the first direction X. The second chip 400 may require higher operating power than the first chip 300, and heat generated in the second chip 400 may be transmitted toward the first chip 300. In plan view, the second chip 400 may be located on the center side of the semiconductor package 1, and at least one first chip 300 may be located on the edge side of the semiconductor package 1 to facilitate heat dissipation. The second chip 400 may also have a physical layer function.

As a non-limiting example, the fourth connection member 540 having electrical conductivity may be located on the connection pad exposed to the bottom surface of the second chip 400. Further, the fourth connection member 540 may be in contact with the connection pad exposed to the top surface of the interposer 200, that is, the second metal layer 230a of the second upper wiring layer 231, and may function as a path for electrical connection between the second chip 400 and the interposer 200. The fourth connection member 540 may be a solder bump, for example, a C4 bump. Although not shown in the drawing, the space between the interposer 200 and the second chip 400 may be filled with an underfill.

According to an exemplary embodiment, one or more of the package substrate 100 and/or the interposer 200, that is, one or more of the first base substrate 110 and the second base substrate 210, may be substantially undoped or regionally non-uniformly doped silicon substrates, which make it possible to form reliable redistribution layers on the silicon substrate while reducing the fabrication cost. Further, the heat dissipation characteristics may be excellent.

Hereinafter, other embodiments of the present disclosure are described. However, descriptions of configurations that are substantially the same or similar to the above-described embodiments are omitted, and these will be easily understood by those skilled in the art from the accompanying drawings.

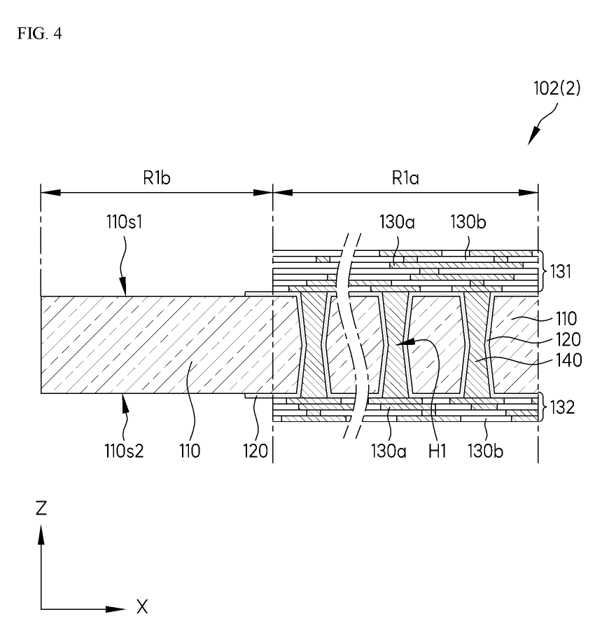

FIG. 4 is a cross-sectional view of a package substrate of a semiconductor package according to another embodiment of the present disclosure.

Referring to FIG. 4, a semiconductor package 2 according to this embodiment includes a package substrate 102, an interposer (not shown), a first chip (not shown), a second chip (not shown), and connection members (not shown), and is different from the embodiment of FIG. 1 in that a top surface 110s1 and a bottom surface 110s2 of the first base substrate 110 are at least partially exposed in the second region R1b of the package substrate 102.

That is, as described above, the first region R1a and the second region R1b are defined on the package substrate 102, and the first region R1a may be defined as a region where the first metal layers 130a of the first wiring layers 131 and 132 are located, and the second region R1b may be defined as a region where the first wiring layers 131 and 132 are not located. Further, the first insulating layer 120 may be directly located on the first base substrate 110 in the first region R1a. In this embodiment, the first insulating layer 120 may partially exist on the first base substrate 110 in the second region R1b, or may not exist. Accordingly, the first base substrate 110 may be exposed without being covered by the first insulating layer 120 and the first wiring layers 131 and 132.

In addition, the materials and bonding relationship of the package substrate 102, the interposer, the first chip, the second chip, and the connection members may be substantially the same as those described above.

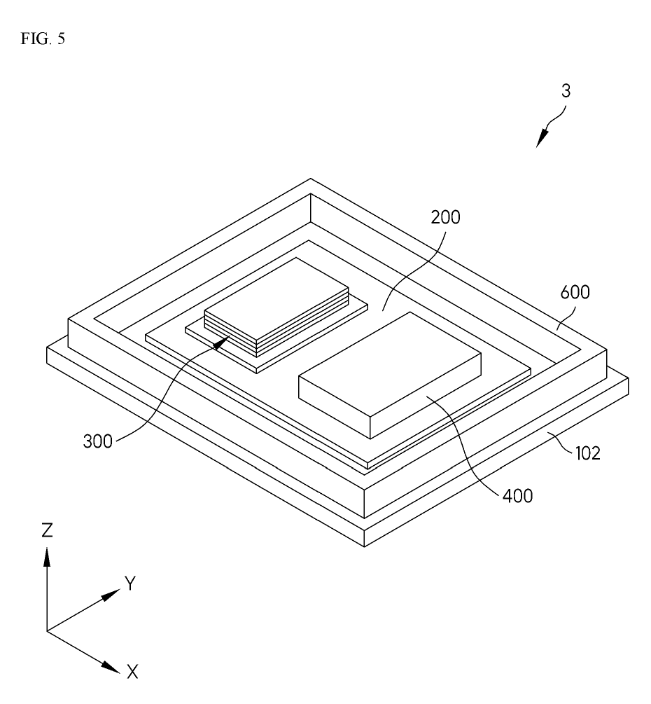

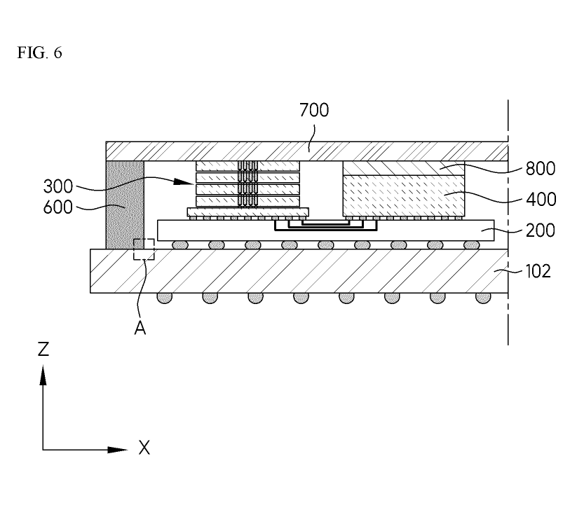

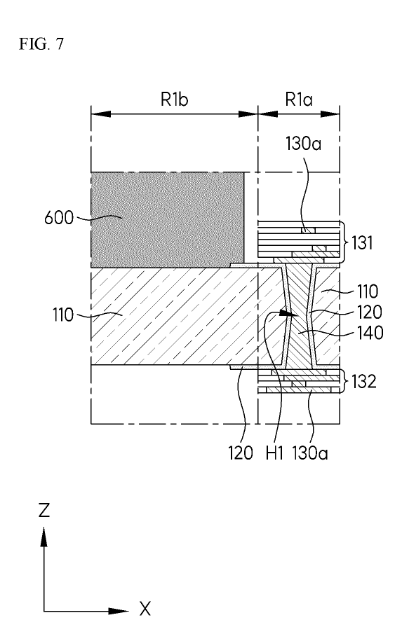

FIG. 5 is a schematic diagram of a semiconductor package 3 according to still another embodiment of the present disclosure. FIG. 6 is a cross-sectional view of a semiconductor package 3 for illustrating the first chip and the second chip. FIG. 7 is an enlarged view showing area A of FIG. 6.

Referring to FIGS. 5 to 7, a semiconductor package 3 according to this embodiment includes a package substrate 102, interposer 200, first chip 300, second chip 400, and connection members, and is different from the embodiment of FIG. 4 in that a support member 600, a heat dissipation member 700, and a spacer 800 are further included.

The support member 600 may have an excellent mechanical strength and may be provided to prevent warping of the semiconductor package 3 even when thermal stress is applied. In plan view, the support member 600 may be located to surround the first chip 300 and the second chip 400. That is, the support member 600 may overlap the first chip 300 and/or the second chip 400 in the first direction X. Furthermore, in plan view, the support member 600 may be located to surround the interposer 200. That is, the support member 600 may overlap the interposer 200 in the first direction X. FIG. 5 illustrates a case where the support member 600 has a substantially quadrilateral band shape including portions extending in the first direction X and portions extending in a second direction Y.

The support member 600 may include a material having excellent formability and excellent strength and rigidity, for example, a metal material such as aluminum, copper, steel, or an alloy thereof, or a carbon-containing composite material.

As described above, the first region R1a and the second region R1b may be defined on the package substrate 102. The second region R1b may be located at the edge compared to the first region R1a, and components understood as the first metal layers 130a of the first wiring layers 131 and 132 may not exist in the second region R1b.

Further, as described in the embodiment of FIG. 4, in the second region R1b, the first base substrate 110 of the package substrate 102 may be at least partially exposed. As described above, the first insulating layer 120 of the package substrate 102 may at least partially exist in the second region R1b. Further, the first base substrate 110 may include silicon or consist of silicon, and the first insulating layer 120 may include at least one of silicon dioxide, silicon nitride, or silicon oxynitride.

In plan view, the support member 600 may be located only in the second region R1b, and may not be located in the first region R1a. In other words, in plan view, the region overlapping the support member 600 in the third direction Z may belong only to the second region R1b.

The support member 600 may be in contact with the package substrate 102 and the heat dissipation member 700. In an exemplary embodiment, the support member 600 may be at least partially in contact with one or more of the first base substrate 110 and the first insulating layer 120 of the package substrate 102. According to this embodiment, the heat dissipation characteristics may be improved by bringing the support member 600 including a metal material and having excellent thermal conductivity into contact with the first base substrate 110 including silicon or consisting of silicon and/or the first insulating layer 120 including silicon. Therefore, damages to the semiconductor package 3 due to heat accumulation may be prevented and the circuit density may be increased.

The heat dissipation member 700 may be located on the support member 600. That is, the heat dissipation member 700 may be spaced apart from the package substrate 102 while the first chip 300, the second chip 400, and/or the interposer 200 may be interposed between the heat dissipation member 700 and the package substrate 102.

The heat dissipation member 700 may have a plate shape that occupies a certain amount of the plane space to which the first direction X and the second direction Y orthogonal to the first direction X belong. The heat dissipation member 700 may include a heat sink and/or a heat spreader of a cooling plate or the like. The heat dissipation member 700 may include copper, aluminum, nickel, iron, and/or an alloy thereof. For example, the heat dissipation member 700 may include nickel-plated copper.

Although not shown in the drawing, a component for bonding the heat dissipation member 700 and the support member 600, for example, a bonding layer, may be located between the heat dissipation member 700 and the support member 600. The bonding layer may include a polymer resin having excellent heat transfer characteristics.

The bottom surface of the heat dissipation member 700 and the second chip 400 may be spaced apart from each other in the third direction Z, and the spacer 800 may be located between the heat dissipation member 700 and the second chip 400. The spacer 800 may be in contact with the heat dissipation member 700 and the second chip 400. The heat dissipation member 700 may include a material that may function as a heat transfer interface, for example, a polymer material and/or metal having high thermal conductivity. The spacer 800 may be interposed between the heat dissipation member 700 and the second chip 400 to improve the mechanical stability of the semiconductor package 3. Although FIG. 6 illustrates a case where the first chip 300 and the heat dissipation member 700 are in contact with each other, the present disclosure is not limited thereto, and a spacer may also be located between the first chip 300 and the heat dissipation member 700 unlike that illustrated in the drawing.

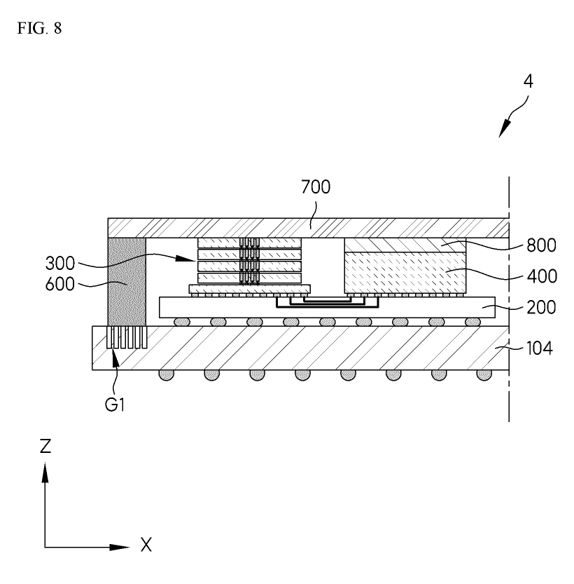

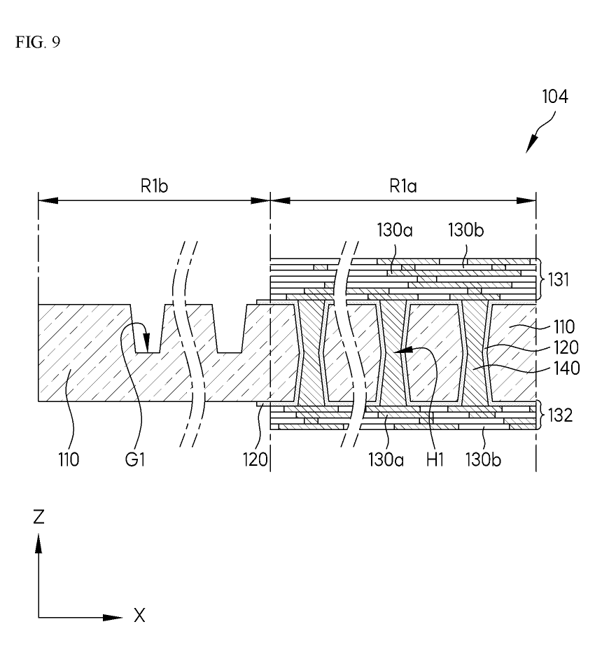

FIG. 8 is a cross-sectional view of a semiconductor package according to still another embodiment of the present disclosure. FIG. 9 is a cross-sectional view of the package substrate of FIG. 8.

Referring to FIGS. 8 and 9, a semiconductor package 4 according to this embodiment includes a package substrate 104, interposer 200, first chip 300, second chip 400, connection members, and support member 600, and is different from the embodiment of FIG. 6 in that at least one groove G1 is formed in the second region R1b of the package substrate 104. The groove G1 may be provided to improve a heat dissipation function.

As described above, the first region R1a and the second region R1b may be defined on the package substrate 104. The second region R1b may be located at the edge compared to the first region R1a, and components understood as the first metal layers 130a of the first wiring layers 131 and 132 may not exist in the second region R1b.

Further, in the second region R1b, the first base substrate 110 of the package substrate 104 may be at least partially exposed. As described above, the first insulating layer 120 of the package substrate 104 may at least partially exist in the second region R1b. Although FIG. 9 illustrates a case where the first insulating layer 120 does not exist in the groove G1, the first insulating layer 120 may be located on the inner sidewalls of at least some of the grooves G1.

The groove G1 according to this embodiment may not overlap the components understood as the first metal layers 130a of the first wiring layers 131 and 132 in the third direction Z. Further, at least some of the grooves G1 formed in the second region R1b may overlap the support member 600 in the third direction Z. Further, at least some of the grooves G1 formed in the second region R1b may overlap the heat dissipation member 700 in the third direction Z. The groove G1 formed in the second region R1b may not overlap the interposer 200 in the third direction Z.

A material understood as a conductive material, such as a metal, may not exist in the groove G1 surrounded by the base surface and the inner sidewall. Since the support member 600 is in contact with the upper portions of the grooves G1 to overlap the grooves G1, at least some of the plurality of grooves G1 may be sealed by the support member 600, and the spaces between the base surfaces of the grooves G1 and the support member 600 may be filled with gas such as air or the like.

The groove G1 of the second region R1b may be formed at the same time with the first via hole H1 of the first region R1a in the same process, but the present disclosure is not limited thereto. In some embodiments, the groove G1 may have a substantially circular shape or a polygonal shape in plan view. In some embodiments, the plurality of grooves G1 spaced apart from each other in the first direction X may each have a line shape extending in the second direction intersecting the first direction X.

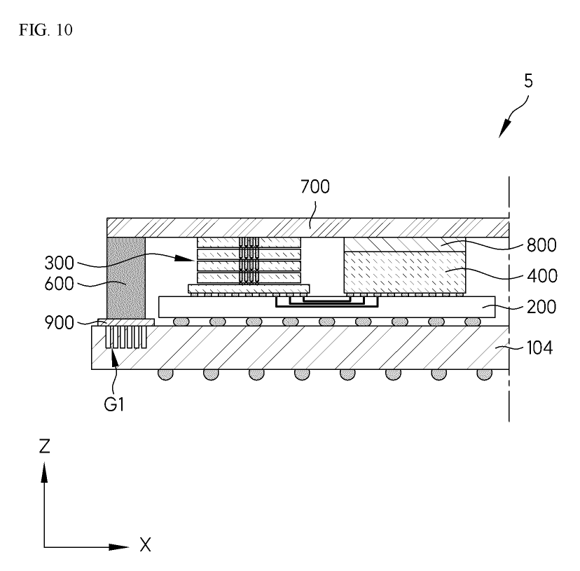

FIG. 10 is a cross-sectional view of a semiconductor package according to still another embodiment of the present disclosure.

Referring to FIG. 10, a semiconductor package 5 according to this embodiment includes a package substrate 104 having the groove G1 formed in the second region, interposer 200, first chip 300, second chip 400, connection members, and support member 600, and is different from the embodiment of FIG. 8 in that the support member 600 and the package substrate 104 are spaced apart from each other and an interlayer 900 located between the support member 600 and the package substrate 104 is further included.

That is, in the previous embodiments, the first insulating layer and/or the first base substrate of the package substrate may be in contact with the support member 600. In contrast, in this embodiment, the interlayer 900 may be located in the second region of the package substrate 104. Here, the interlayer 900 may be in contact with the first insulating layer (e.g., silicon dioxide or the like) and/or the first base substrate (i.e., silicon) of the package substrate 104, and the interlayer 900 may be in contact with the support member 600. The interlayer 900 in contact with the package substrate 104 and/or the support member 600 may be located only in the second region.

The interlayer 900 may include a polymer resin and/or a metal material having high thermal conductivity. That is, the interlayer 900 may function as a thermal interface.

At least some or all of the grooves G1 formed in the second region of the package substrate 104 may overlap the interlayer 900 in the third direction Z. Further, the interlayer 900 may not overlap the interposer 200 in the third direction Z. As a non-limiting example, both the interlayer 900 and the support member 600 may be made of a metal material, but the interlayer 900 may be distinguished from the support member 600 in that it does not overlap the first chip 300, the second chip 400, and/or the interposer 200 in the first direction X. The method of forming the interlayer 900 is not particularly limited, and metal paste printing or the like may be used.

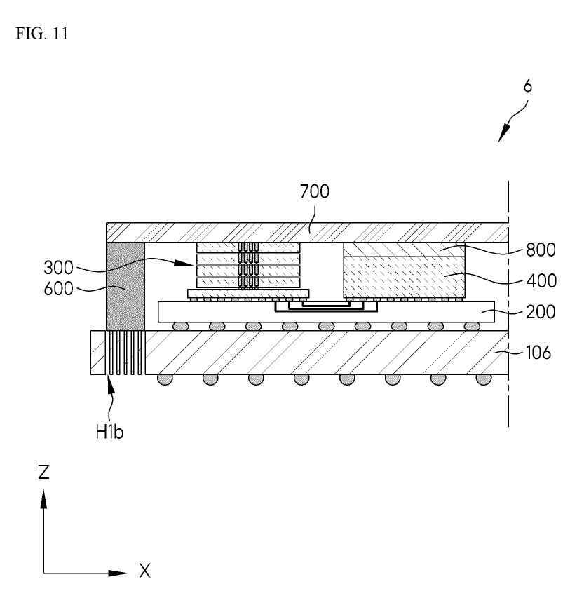

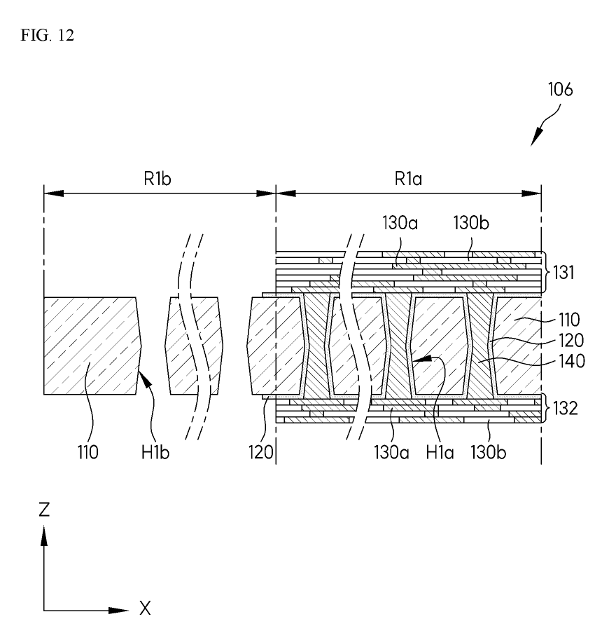

FIG. 11 is a cross-sectional view of a semiconductor package according to still another embodiment of the present disclosure. FIG. 12 is a cross-sectional view of the package substrate of FIG. 11.

Referring to FIGS. 11 and 12, a semiconductor package 6 according to this embodiment includes a package substrate 106, interposer 200, first chip 300, second chip 400, connection members, and support member 600, and is different from the embodiment of FIG. 6 in that at least one first-second hole H1b is formed in the second region R1b of the package substrate 106. The first-second hole H1b may be provided to improve a heat dissipation function.

As described above, the first region R1a and the second region R1b may be defined on the package substrate 106. The second region R1b may be located at the edge compared to the first region R1a, and components understood as the first metal layers 130a of the first wiring layers 131 and 132 may not exist in the second region R1b.

A first-first via hole H1a may be located in the first region R1a. The first-first via hole H1a may overlap components understood as the first wiring layers 131 and 132 or the first metal layers 130a of the first wiring layers 131 and 132 in the third direction Z. Further, the first-first via hole H1a may be filled with the first conductive portion 140. The first-first via hole H1a may overlap the interposer 200 in the third direction Z.

Further, in the second region R1b, the first base substrate 110 of the package substrate 106 may be at least partially exposed. As described above, the first insulating layer 120 of the package substrate 106 may at least partially exist in the second region R1b. Although FIG. 12 illustrates a case where the first insulating layer 120 does not exist in the first-second hole H1b, the first insulating layer 120 may be located on at least a part of the inner sidewall of the first-second hole H1b.

The first-second hole H1b according to this embodiment may not overlap the components understood as the first metal layers 130a of the first wiring layers 131 and 132 in the third direction Z. Further, at least some of the first-second holes H1b formed in the second region R1b may overlap the support member 600 in the third direction Z. Further, at least some of the first-second holes H1b formed in the second region R1b may overlap the heat dissipation member 700 in the third direction Z. The first-second hole H1b formed in the second region R1b may not overlap the interposer 200 in the third direction Z.

A material understood as a conductive material, such as a metal, may not exist in the inner sidewall of the first-second hole H1b. Since the support member 600 may be in contact with the upper portions of the first-second holes H1b to overlap the first-second holes H1b, the upper openings of at least some of the plurality of first-second holes H1b may be sealed by the support member 600, and the first-second hole H1b may be filled with gas such as air or the like. Further, the bottom surface of the support member 600 may be exposed through the lower opening of the first-second hole H1b.

The first-second hole H1b of the second region R1b may be formed at the same time with the first-first via hole H1a of the first region R1a in the same process, but the present disclosure is not limited thereto. In some embodiments, the first-second hole H1b may have a substantially circular shape or a polygonal shape in plan view. In some embodiments, the plurality of first-second holes H1b spaced apart from each other in the first direction X may each have a line shape extending in the second direction intersecting the first direction X.

The sizes, e.g., the maximum diameters in plan view, of the first-first via hole H1a and the first-second hole H1b may be different. Specifically, the maximum diameter of the first-second hole H1b may be greater than the maximum diameter of the first-first via hole H1a. The maximum diameter of the first-first via hole H1a may be about 30 μm or less, about 20 μm or less, or about 10 μm or less, and the minimum diameter of the first-second hole H1b may be greater than that of the first-first via hole H1a.

That is, the first base substrate 110 of the package substrate 106 according to this embodiment may have the plurality of via holes H1a and H1b, and among the via holes H1a and H1b, the via hole that is filled with the first conductive portion 140 may be referred to as the first-first via hole H1a, and the via hole that is not filled with a conductive material such as a metal or the like may be referred to as the first-second hole H1b. Further, at least some of the first-second holes H1b may overlap the support member 600 in the third direction Z.

In another embodiment, unlike that illustrated in the drawing, both the first-second hole H1b and a groove for heat dissipation may be located in the second region R1b.

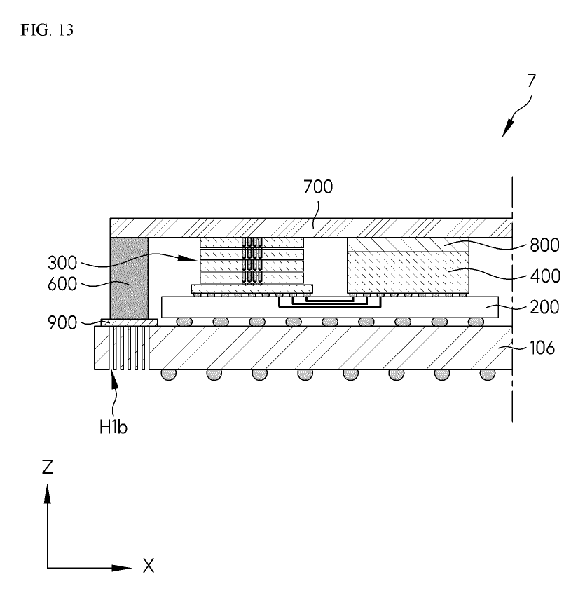

FIG. 13 is a cross-sectional view of a semiconductor package according to still another embodiment of the present disclosure.

Referring to FIG. 13, a semiconductor package 7 according to this embodiment includes a package substrate 106 having the first-second hole H1b formed in the second region, interposer 200, first chip 300, second chip 400, connection members, and support member 600, and is different from the embodiment of FIG. 11 in that the support member 600 and the package substrate 106 are spaced apart from each other, and the interlayer 900 located between the support member 600 and the package substrate 106 is further included.

The material of the interlayer 900 and the bonding relationship between the interlayer 900 and another component may be substantially the same as those described in FIG. 10.

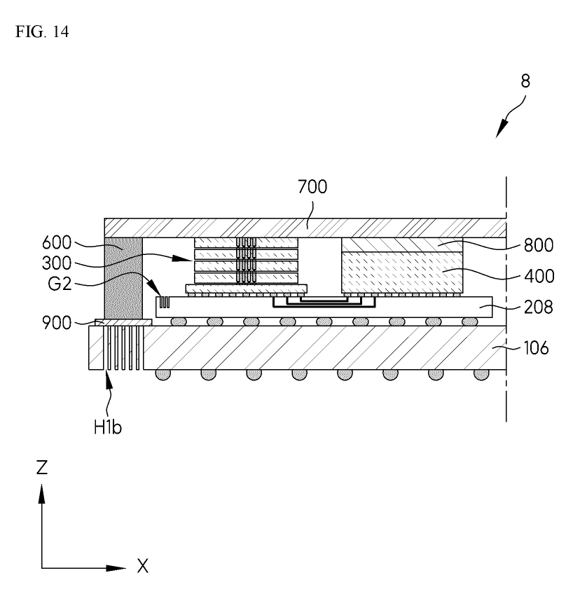

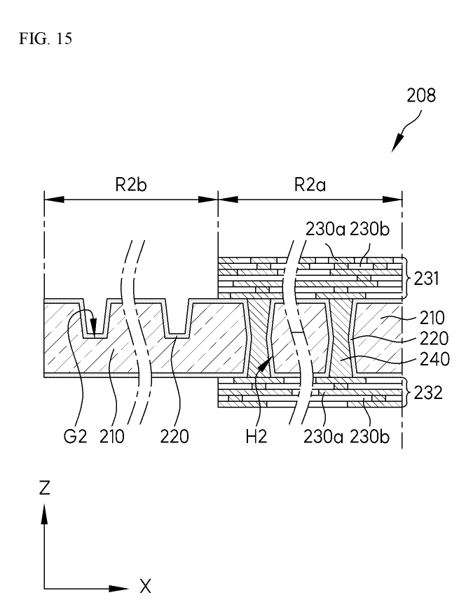

FIG. 14 is a cross-sectional view of a semiconductor package according to still another embodiment of the present disclosure. FIG. 15 is a cross-sectional view of the interposer of FIG. 14.

Referring to FIGS. 14 and 15, a semiconductor package 8 according to this embodiment includes a package substrate 106, interposer 208, first chip 300, second chip 400, connection members, and support member 600, and is different from the embodiment of FIG. 13 in that the interposer 208 has a second groove G2. The second groove G2 may be provided to improve a heat dissipation function.

A first region R2a (or second-first region) and a second region R2b (or second-second region) may be defined in the interposer 208. The first region R2a may be defined as a region where the second wiring layers 231 and 232 are located, and the second region R2b may be defined as a region where the second wiring layers 231 and 232 are not located. More specifically, at least the second metal layers 230a of the second wiring layers 231 and 232 may not exist in the second region R2b. In plan view, the second region R2b may have a shape that at least partially surrounds the first region R2a.

As described above in FIG. 3, the second base substrate 220 of the interposer 208 may have the plurality of second via holes H2 filled with the second conductive portion 240, and the second via holes H2 may exist in the first region R2a. The second base substrate 210 and the second insulating layer 220 may exist in the second region R2b. Although FIG. 15 illustrates a case where the second insulating layer 220 is located on the inner sidewall of the second groove G2 of the second base substrate 210, in another embodiment, the second base substrate 210 in the second region R2b may be at least partially exposed, and/or the second groove G2 may be at least partially exposed without being covered by the second insulating layer 220.

The second grooves G2 according to this embodiment may not overlap the components understood as the second metal layers 230a of the second wiring layers 231 and 232 in the third direction Z. Further, the second grooves G2 formed in the second region R2b of the interposer 208 may not overlap the support member 600 in the third direction Z. Further, the second grooves G2 formed in the second region R2b of the interposer 208 may not overlap the first chip 300 and/or the second chip 400 in the third direction Z. As a non-limiting example, the second groove G2 formed in the second region R2b of the interposer 208 may overlap the first region R1a of the package substrate 106 in the third direction Z.

A material understood as a conductive material, such as a metal, may not exist in the second groove G2 surrounded by the base surface and the inner sidewall. The second groove G2 may be filled with gas such as air or the like.

The second groove G2 of the second region R2b of the interposer 208 may be formed at the same time with the second via hole H2 of the first region R2a of the interposer 208 in the same process, but the present disclosure is not limited thereto. In some embodiments, the second groove G2 may have a substantially circular shape or a polygonal shape in plan view. In some embodiments, the plurality of second grooves G2 spaced apart from each other in the first direction X may each have a line shape extending in the second direction intersecting the first direction X.

Although FIG. 14 illustrates a case where the first-second hole H1b is formed in the second region of the package substrate 106, the first groove may be formed in the second region of the package substrate 106.

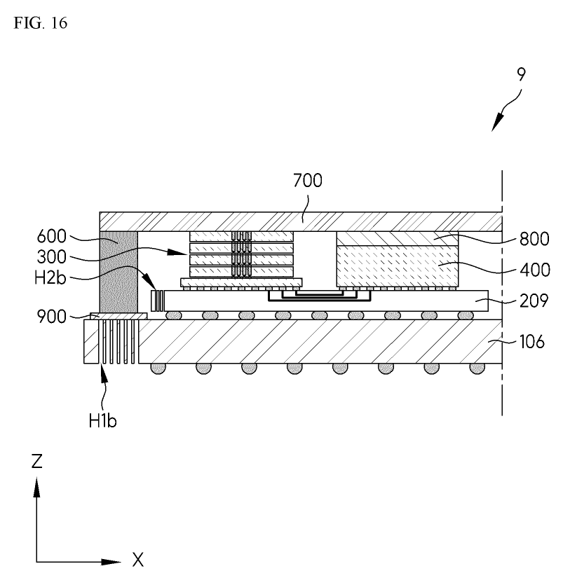

FIG. 16 is a cross-sectional view of a semiconductor package according to still another embodiment of the present disclosure.

Referring to FIG. 16, a semiconductor package 9 according to this embodiment includes a package substrate 106, interposer 209, first chip 300, second chip 400, connection members, and support member 600, and is different from the embodiment of FIG. 14 in that at least one second-second hole H2b is formed in the second region of the interposer 209. The second-second hole H2b may be provided to improve a heat dissipation function.

The second-second hole H2b is different from the second groove of FIG. 14 in that it penetrates the second base substrate of the interposer 209 in the third direction Z. In addition, the arrangement relationship of the second-second hole H2b or the like may be substantially the same as that described in FIG. 14.

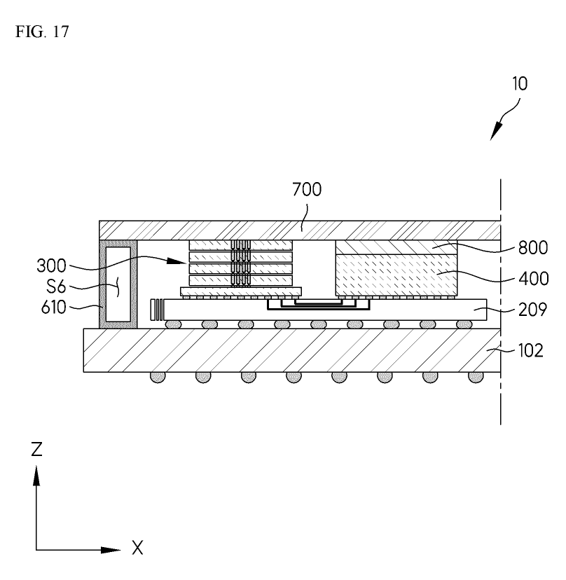

FIG. 17 is a cross-sectional view of a semiconductor package according to still another embodiment of the present disclosure.

Referring to FIG. 17, a semiconductor package 10 according to this embodiment includes a package substrate 102, interposer 209, first chip 300, second chip 400, connection members, and support member 610, and is different from the embodiment of FIG. 6 in that the support member 610 has a fluid space S6 therein.

The support member 610 may be located to at least partially surround the first chip 300, the second chip 400, and/or the interposer 209, and may overlap the first chip 300, the second chip 400, and/or the interposer 209 in the first direction X. The support member 610 may include a metal material such as aluminum, copper, steel, or an alloy thereof, or a carbon-containing composite material.

In cross-sectional view of the support member 610, the support member 610 may have a substantially quadrilateral band shape and may have the fluid space S6 (or internal space) therein. The fluid space S6 may be filled with gas such as air or fluid such as liquid. When the support member 610 includes portions extending in the first direction X and the second direction in plan view, the fluid spaces in first portions extending in the first direction X may be fluidly connected to the fluid spaces S6 in second portions extending in the second direction.

As described above, the support member 610 may be in contact with the first insulating layer and/or the first base substrate of the package substrate 102.

Although not shown in the drawing, a hole and/or a groove for enhancing the heat dissipation function may be formed in the second region (i.e., the region where the wiring layer is not formed) of each of the interposer and/or the package substrate.

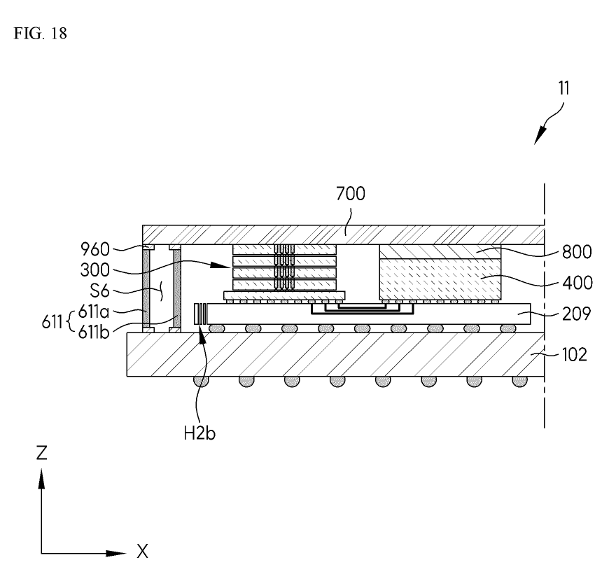

FIG. 18 is a cross-sectional view of a semiconductor package according to still another embodiment of the present disclosure.

Referring to FIG. 18, a semiconductor package 11 according to this embodiment includes a package substrate 102, interposer 209, first chip 300, second chip 400, connection members, and support member 611 having the fluid space S6, and is different from the embodiment of FIG. 17 in that the support member 611 includes a first wall portion 611a and a second wall portion 611b spaced apart from each other in the horizontal direction, and the support member 611 is spaced apart from the package substrate 102 and/or the heat dissipation member 700.

The first wall portion 611a may be spaced apart from the second wall portion 611b in the first direction X to be located on the edge side. The fluid space S6 may be defined in the separation space between the first wall portion 611a and the second wall portion 611b in the first direction X.

The bottom surface of the heat dissipation member 700 and/or the top surface of the package substrate 102 may be directly exposed to the fluid space S6. Specifically, the first insulating layer and/or the top surface of the first base substrate of the package substrate 102 may be at least partially directly exposed to the fluid space S6.

An interlayer 960, for example, a sealing layer, may be located between the support member 611 and the package substrate 102 and between the support member 611 and the heat dissipation member 700. The material of the interlayer 960 may be substantially the same as that described above.

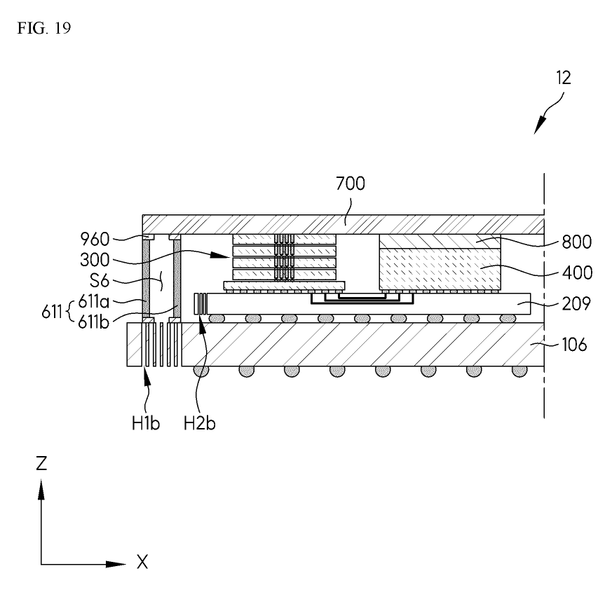

FIG. 19 is a cross-sectional view of a semiconductor package according to still another embodiment of the present disclosure.

Referring to FIG. 19, a semiconductor package 12 according to this embodiment includes a package substrate 106, interposer 209, first chip 300, second chip 400, connection members, and support member 611 having the fluid space S6, and is different from the embodiment of FIG. 18 in that at least one first-second hole H1b is formed in the second region of the package substrate 106, and the first-second hole H1b is connected to the fluid space S6.

The first-second hole H1b formed in the second region of the package substrate 106 is substantially the same as that described above in FIG. 11.

In the semiconductor package 12 according to this embodiment, the fluid space S6 and the first-second hole H1b may be fluidly connected. The fluid space S6 and the first-second hole H1b may be filled with gas and/or liquid.

In another embodiment, unlike that illustrated the drawing, a groove for heat dissipation may be formed in the second region of the package substrate, and the groove may be fluidly connected to the fluid space S6.

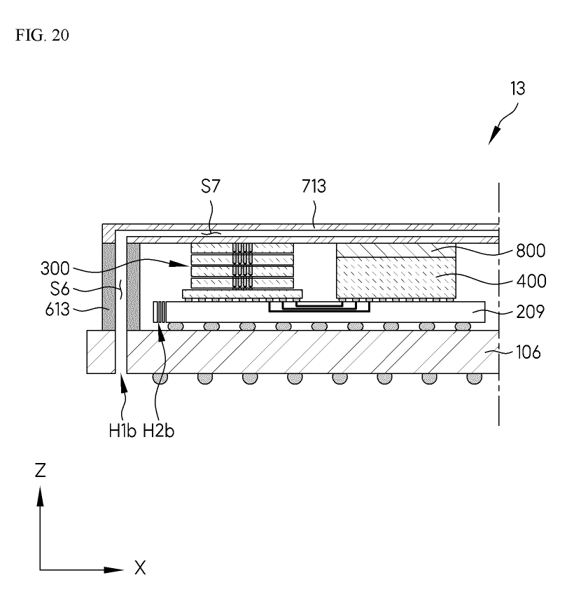

FIG. 20 is a cross-sectional view of a semiconductor package according to still another embodiment of the present disclosure.

Referring to FIG. 20, a semiconductor package 13 according to this embodiment includes a package substrate 106 having the first-second hole H1b, interposer 209, first chip 300, second chip 400, connection members, support member 613 having the first fluid space S6 connected to the first-second hole H1b, and heat dissipation member 713, and is different from the embodiment of FIG. 19 in that the heat dissipation member 713 has a second fluid space S7.

The second fluid space S7 formed in the heat dissipation member 713 may be fluidly connected to the first fluid space S6 and the first-second hole H1b. The first-second hole H1b, the first fluid space S6, and the second fluid space S7 may be filled with gas or liquid.

The second fluid space S7 may have a shape extending in the horizontal direction. Specifically, the second fluid space S7 may include flow paths extending in the first direction X and/or the second direction so that the second fluid space S7 may occupy a sufficient area in plan view. Further, the second fluid space S7 may at least partially overlap the interposer 209, the first chip 300, and/or the second chip 400 in the third direction Z.

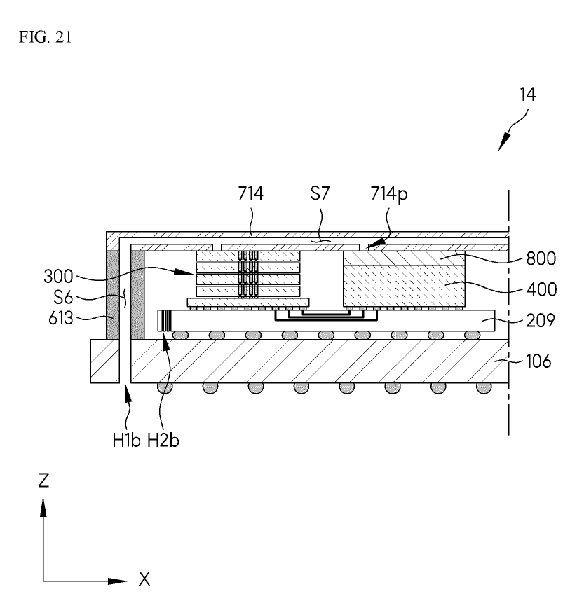

FIG. 21 is a cross-sectional view of a semiconductor package according to still another embodiment of the present disclosure.

Referring to FIG. 21, a semiconductor package 14 according to this embodiment includes a package substrate 106 having the first-second hole H1b, interposer 209, first chip 300, second chip 400, connection members, support member 613 having the first fluid space S6, and heat dissipation member 714 having the second fluid space S7, and is different from the embodiment of FIG. 20 in that an opening 714p is formed on a bottom surface of the heat dissipation member 714.

The lower opening 714p formed in the heat dissipation member 714 may overlap the first chip 300 and/or the second chip 400 in the third direction Z.

Although not illustrated in the drawing, the first chip 300 and/or the second chip 400 may have a through hole penetrating in the third direction Z. As a non-limiting example, when the first chip 300 includes a plurality of stacked dies, each of the plurality of dies may have a through hole in the third direction Z, and the through hole may be empty. Further, the through hole may be connected to the opening 714p, and the fluid in the first fluid space S6 and the second fluid space S7 may be connected to the through hole formed in the first chip 300 and/or the second chip 400.

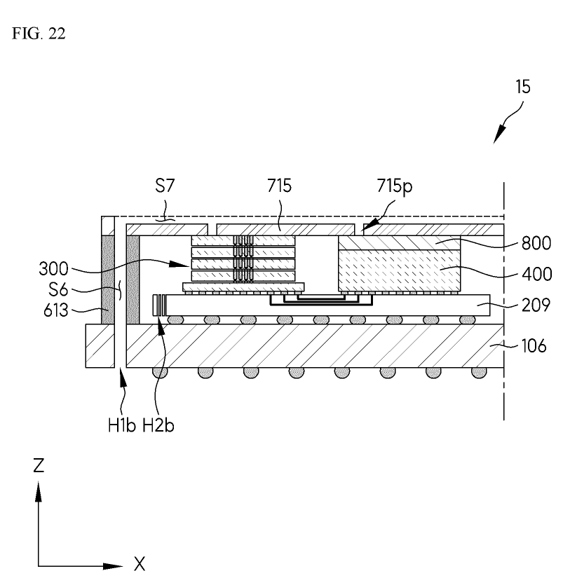

FIG. 22 is a cross-sectional view of a semiconductor package according to still another embodiment of the present disclosure.

Referring to FIG. 22, a semiconductor package 15 according to this embodiment includes a package substrate 106 having the first-second hole H1b, interposer 209, first chip 300, second chip 400, connection members, support member 613 having the first fluid space S6, and heat dissipation member 715 having the second fluid space S7 and a lower opening 715p, and is different from the embodiment of FIG. 21 in that the second fluid space S7 of the heat dissipation member 715 is implemented as a groove exposed to a top surface, instead of an internal flow path shape.

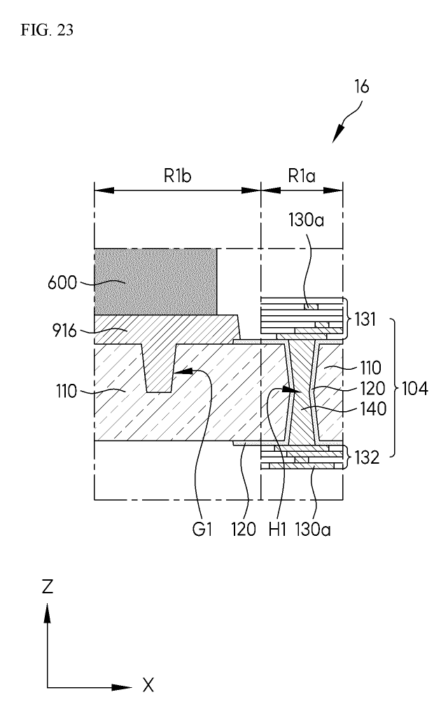

FIG. 23, which is a cross-sectional view of a semiconductor package 16 according to still another embodiment of the present disclosure, is a cross-sectional view showing the vicinity of the package substrate 104 and the support member 600.

Referring to FIG. 23, a semiconductor package 16 according to this embodiment includes a package substrate 104 having the groove G1 formed in the second region R1b, an interposer (not shown), a first chip (not shown), a second chip (not shown), connection members (not shown), support member 600, and interlayer 916, and is different from the embodiment of FIG. 10 in that the groove G1 is at least partially filled with the interlayer 916.

When the interlayer 916 includes a material having electrical conductivity such as a metal material, the interlayer 916 may be electrically insulated from the components understood as the first metal layers 130a in the first wiring layers 131 and 132. Although the present disclosure is not limited thereto, the interlayer 916 may be in contact with one or more of the first base substrate 110 and/or the first insulating layer 120. The interlayer 916 may not overlap the first chip, the second chip, and/or the interposer in the first direction X.

In addition, the materials and bonding relationship of the package substrate 104, the interposer, the first chip, the second chip, and the connection members may be substantially the same as those described above.

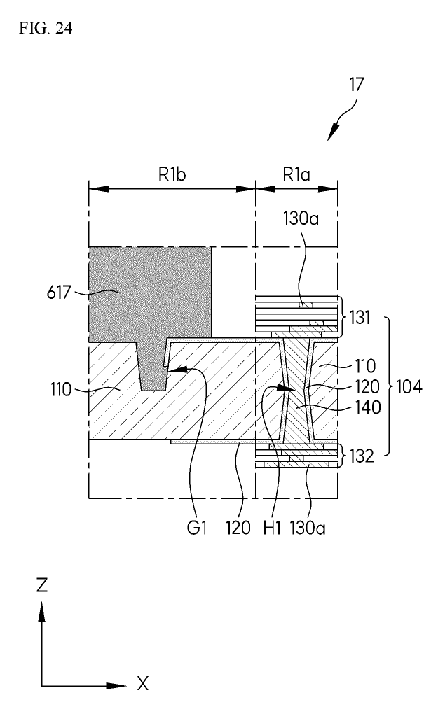

FIG. 24, which is a cross-sectional view of a semiconductor package 17 according to still another embodiment of the present disclosure, is a cross-sectional view showing the vicinity of the package substrate 104 and a support member 617.

Referring to FIG. 24, a semiconductor package 17 according to this embodiment includes a package substrate 104 having the groove G1 formed in the second region R1b, an interposer (not shown), a first chip (not shown), a second chip (not shown), connection members (not shown), and support member 617, and is different from the embodiment of FIG. 23 in that the groove G1 is at least partially filled with the support member 617.

In this embodiment, the support member 617 may be in contact with the first base substrate 110. Furthermore, the support member 617 may be at least partially in contact with the first insulating layer 120.

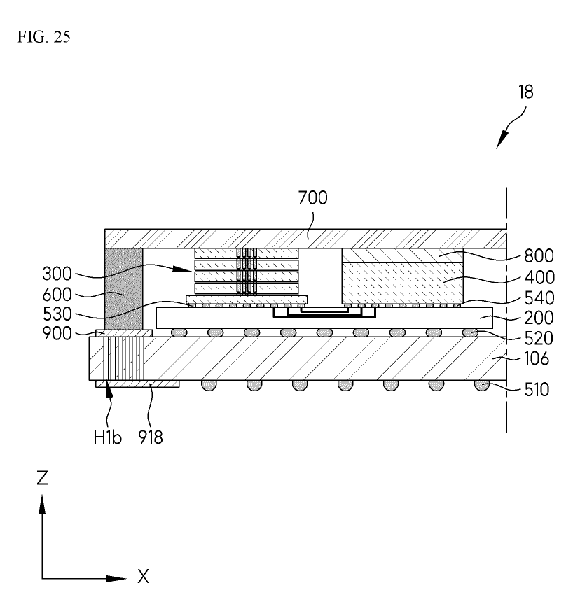

FIG. 25 is a cross-sectional view of a semiconductor package according to still another embodiment of the present disclosure.

Referring to FIG. 25, a semiconductor package 18 according to this embodiment includes a package substrate 106 having the first-second hole H1b formed in the second region, interposer 200, first chip 300, second chip 400, connection members 510, 520, 530, and 540, support member 600, and interlayer 900 located on the top surface of the package substrate 106, and is different from the embodiment of FIG. 13 in that a rear heat dissipation member 918 located on a bottom surface of the package substrate 106 is further included.

The material of the rear heat dissipation member 918 may be substantially the same as or different from that of the interlayer 900. Further, the rear heat dissipation member 918 may be located to at least partially overlap the interlayer 900 in the third direction Z. The interlayer 900 may be located only in the second region of the package substrate 106, but the rear heat dissipation member 918 may be located at least partially in the second region of the package substrate 106, and may be located at least partially in the first region of the package substrate 106. The rear heat dissipation member 918 may at least partially overlap the first connection member 510 in the first direction X, but the rear heat dissipation member 918 may not overlap the first connection member 510 in the third direction Z. Further, the rear heat dissipation member 918 and the first connection member 510 may include different materials.

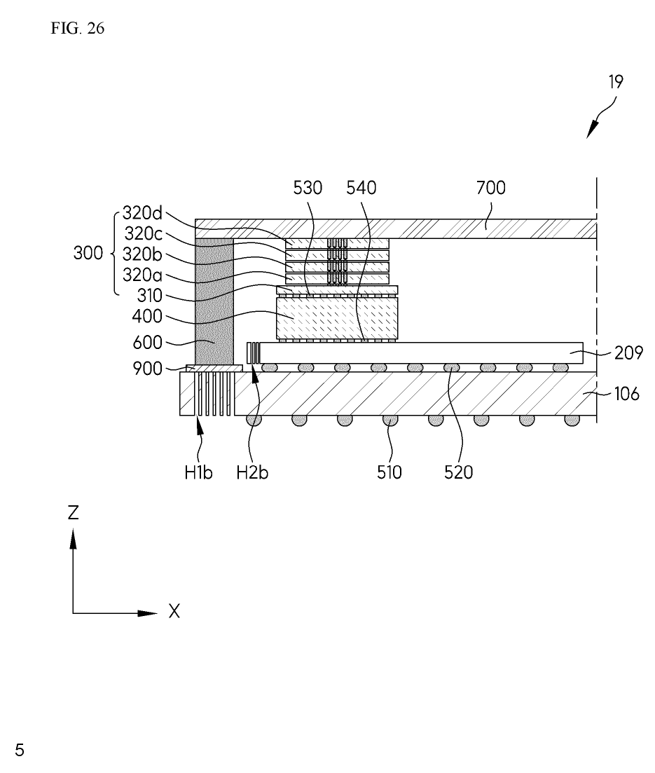

FIG. 26 is a cross-sectional view of a semiconductor package according to still another embodiment of the present disclosure.

Referring to FIG. 26, a semiconductor package 19 according to this embodiment includes a package substrate 106, interposer 209, first chip 300, second chip 400, and connection members 510, 520, 530, and 540, and is different from the embodiment of FIG. 16 in that the first chip 300 and the second chip 400 are stacked to overlap in the third direction Z.

In this embodiment, the third connection member 530 may connect the first chip 300 to the activated connection pad on the top surface of the second chip 400 instead of connecting the first chip 300 to the interposer 209. In addition, the materials and arrangement relationship of the package substrate 106 and the interposer 209 may be substantially the same as those described above.

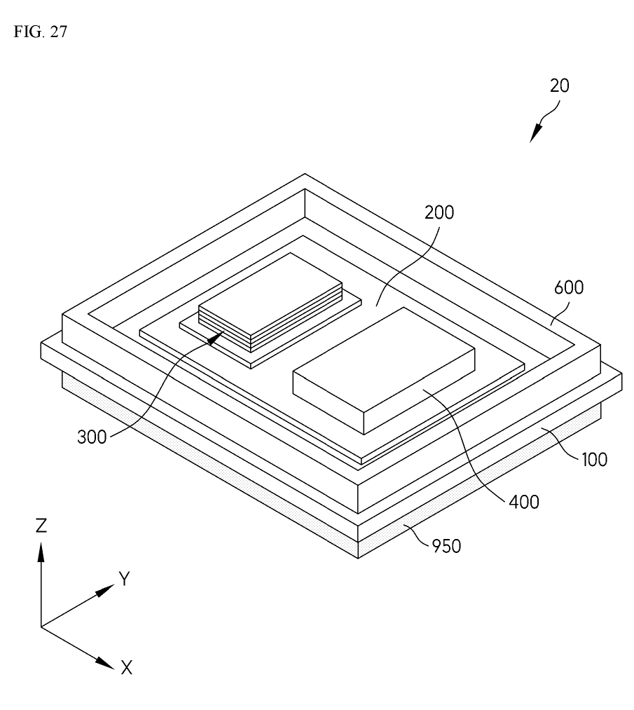

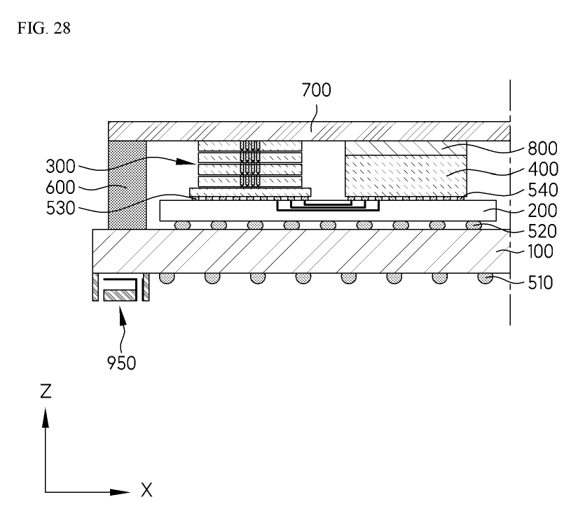

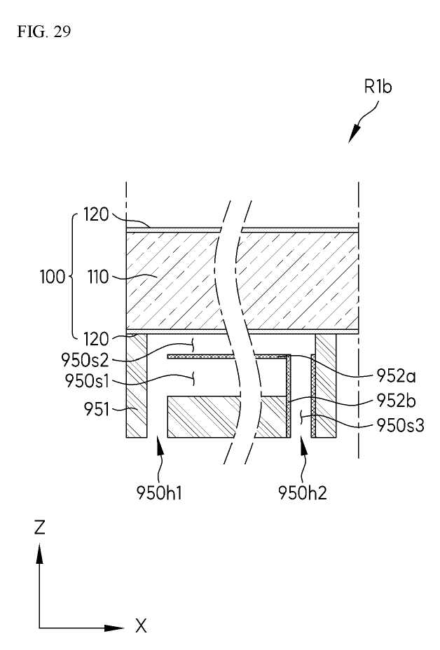

FIG. 27 is a schematic diagram of a semiconductor package 20 according to still another embodiment of the present disclosure. FIG. 28 is a cross-sectional view of a semiconductor package 20. FIG. 29 is an enlarged view showing the vicinity of a cooling member and a package substrate of FIG. 28.

Referring to FIGS. 27 to 29, a semiconductor package 20 according to this embodiment includes a package substrate 100, interposer 200, first chip 300, second chip 400, connection members 510, 520, 530, and 540, and support member 600, and is different from the embodiment of FIG. 6 in that a cooling member 950 is further included.

As described above, the first region and the second region R1b may be defined on the package substrate 100. The second region R1b may be located at the edge compared to the first region, and components understood as the first metal layers 130a of the first wiring layers 131 and 132 may not exist in the second region R1b.

Additionally, the first base substrate 110 and the first insulating layer 120 may exist in the second region R1b. Although not shown in the drawing, a groove or hole may exist in the second region R1b of the package substrate 100.

The support member 600 and the cooling member 950 may be located in the second region R1b of the package substrate 100. The support member 600 and the cooling member 950 may at least partially overlap each other in the third direction Z. The support member 600 and/or the cooling member 950 may be in contact with the first insulating layer 120. Unlike that illustrated in the drawing, the first base substrate 110 in the second region R1b may be exposed, and the first base substrate 110 may be in contact with the support member 600 and/or the cooling member 950.

The cooling member 950 may be provided to cool the first base substrate 110 of the package substrate 100. In an exemplary embodiment, the cooling member 950 may have internal cooling spaces 950s1, 950s2, and 950s3, and may be arranged to surround the first connection member 510 in plan view. That is, the cooling member 950 may overlap the first connection member 510 in the first direction X. FIG. 27 illustrates a case where the cooling member 950 has a substantially quadrilateral band shape including portions extending in the first direction X and portions extending in the second direction Y.

The cooling member 950 may include a cooling member body portion 951, and the cooling member body portion 951 may occupy a selected plane space to which the first direction X and the second direction Y belong and overlap the package substrate 100 in the third direction Z. Additionally, the cooling member body portion 951 may have a first hole 950h1 (or a coolant inlet hole) and a second hole 950h2 (or a coolant discharge hole). FIG. 28 illustrates a case where the first hole 950h1 and the second hole 950h2 are formed on the bottom side of the cooling member body portion 951, but the present disclosure is not limited thereto.

The cooling member 950 may further include a passage member 952. For example, the passage member 952 may include a first passage portion 952a including a portion extending in the first direction X and a second passage portion 952b extending in the third direction Z. The first passage portion 952a may have a substantially plate shape in plan view, and may divide the internal space of the cooling member body portion 951 into a first cooling space 950s1 on the lower side and a second cooling space 950s2. Further, the second passage portion 952b may have a substantially tubular shape extending in the third direction Z and may define a third cooling space 950s3 therein. The third cooling space 950s3 may be fluidly connected to the second cooling space 950s2. The upper part of the second passage portion 952b may be located adjacent to the package substrate 100. Accordingly, a flow path may be formed such that a coolant introduced through the first hole 950h1 is discharged into the second hole 950h2 only after sufficiently filling the cooling spaces 950s1 and 950s2 to contribute to the cooling of the package substrate 100, rather than being immediately discharged into the second hole 950h2. In another embodiment, the first passage portion 952a may be omitted.

The second cooling space 950s2 of the cooling member 950 configured as described above may be in contact with the first insulating layer 120 (or the first base substrate 110) in the second region R1b of the package substrate 100. That is, the bottom surface of the first insulating layer 120 may define the second cooling space 950s2. In other words, the first passage portion 952a may directly face the first insulating layer 120 (or the first base substrate 110) in the third direction Z. In further other words, a coolant fluid flowing along the second cooling space 950s2 may be directly in contact with the first insulating layer 120 (or the first base substrate 110).

According to this embodiment, the coolant fluid such as gas or liquid may fill the first cooling space 950s1 through the first hole 950h1. Then, the coolant fluid filled in the first cooling space 950s1 may flow into the second cooling space 950s2 and flow along the first direction X, thereby contributing to the cooling of the package substrate 100. Then, the coolant fluid may be discharged into the second hole 950h2 through the third cooling space 950s3.

The package substrate 100 and the cooling member 950 can be joined in various ways. For example, various methods such as adhesive bonding, vitrification bonding, solder bonding, epoxy bonding, die attach film, oxide bonding, and fusion bonding may be used.

Although the preferred embodiments have been described above, they are merely examples and not intended to limit any embodiments and it should be appreciated that various modifications and applications not described above may be made by one of ordinary skill in the art without departing from the embodiments.

Therefore, it should be understood that the scope of the present disclosure includes changes, equivalents or substitutes of the technical concept described above. For example, each component specifically shown in the embodiment of the present disclosure may be modified and implemented. In addition, it should be understood that differences related to these modifications and applications are within the scope of the present disclosure.

1. A semiconductor package comprising:
a package substrate comprising a first base substrate and a first wiring layer;
an interposer comprising a second base substrate and a second wiring layer, and located on the package substrate;
a first chip located on the interposer; and
a second chip located on the interposer,
wherein one or more of the first base substrate and the second base substrate are silicon (Si) substrates which are substantially undoped or regionally non-uniformly doped.

2. The semiconductor package of claim 1, wherein the first chip is a memory element, and the second chip is a processing element.

3. The semiconductor package of claim 1, wherein the first base substrate is an undoped silicon substrate, and
a silicon purity of the silicon substrate is 99.99% or more and 99.99999999% or less.

4. The semiconductor package of claim 3, wherein the silicon substrate does not substantially contain phosphorus (P) and boron (B), and
the silicon substrate has a polycrystalline structure or an amorphous structure.

5. The semiconductor package of claim 1, wherein the first base substrate comprises a non-uniformly doped silicon substrate, which is partially doped with boron (B) or phosphorus (P),
a resistivity of the silicon substrate ranges from several hundred Ω·cm to several thousand Ω·cm, and
the silicon substrate has a band gap of 9.1 eV or more, or a breakdown voltage of 10 MV/cm or more.

6. The semiconductor package of claim 1, further comprising a cooling member located on a bottom surface of the package substrate,
wherein a coolant fluid flowing along an internal space of the cooling member is in contact with an insulating layer of the package substrate.

7. The semiconductor package of claim 1, further comprising a support member located on the package substrate and at least partially surrounding the interposer.

8. The semiconductor package of claim 7, wherein a first region and a second region are defined on the package substrate, and
in plan view, the support member is located in the second region and is not located in the first region.

9. The semiconductor package of claim 8, wherein the first base substrate is made of silicon (Si),
the first wiring layer comprises a metal layer, and the metal layer does not exist in the second region.

10. The semiconductor package of claim 9, wherein the package substrate further comprises an insulating layer directly located on the first base substrate, and
in the second region, the insulating layer is at least partially exposed, and the insulating layer is in contact with the support member.

11. The semiconductor package of claim 9, wherein in the second region, the first base substrate is at least partially exposed, and the first base substrate is in contact with the support member.

12. The semiconductor package of claim 8, wherein the first base substrate has a plurality of holes, and
the plurality of holes comprise at least one second hole located in the second region.

13. The semiconductor package of claim 12, wherein the second hole overlaps the support member in a lamination direction.

14. The semiconductor package of claim 8, wherein the first base substrate has at least one groove located in the second region, and
the at least one groove overlaps the support member in a lamination direction.

15. The semiconductor package of claim 8, wherein the first base substrate has at least one hole and/or groove located in the second region,
the semiconductor package further comprising a thermal interface interlayer overlapping the at least one hole and/or groove and in contact with the support member and the package substrate.

16. The semiconductor package of claim 8, wherein the support member has a first fluid space.

17. The semiconductor package of claim 16, wherein the first base substrate has at least one hole located in the second region, and
the at least one hole is connected to the first fluid space.

18. The semiconductor package of claim 16, further comprising a heat dissipation member located on the support member and spaced apart from the package substrate with the interposer located between the heat dissipation member and the package substrate,
wherein the heat dissipation member has a second fluid space, and
the second fluid space is connected to the first fluid space.

19. The semiconductor package of claim 18, wherein the second fluid space at least partially overlaps the first chip or the second chip in the lamination direction.

20. The semiconductor package of claim 16, wherein the first fluid space is filled with liquid.
